(19) United States
(12) Patent Application Publication
(10) Pub. No.: US 2024/0183916 A1
(43) Pub. Date: Jun. 6, 2024

(54) METHOD FOR EVALUATING BUILDING ROOF PHOTOVOLTAIC POWER QUALITY BASED ON AHP AND CRITIC-ENTROPY

(71) Applicant: HUANENG JIANGSU COMPREHENSIVE ENERGY SERVICE CO., LTD., Nanjing (CN)

(72) Inventors: Feng LI, Nanjing (CN); Xuliang JIANG, Nanjing (CN); Fan BIAN, Nanjing (CN); Chenhui NIU, Nanjing (CN); Xi GUO, Nanjing (CN); Ying ZHANG, Nanjing (CN); Jie YIN, Nanjing (CN); Kenan CAO, Nanjing (CN); Yang YANG, Nanjing (CN)

(21) Appl. No.: 18/151,411

(22) Filed: Jan. 6, 2023

(30) Foreign Application Priority Data
Oct. 25, 2022 (CN) 202211313018.8

(51) Int. Cl. G01R 31/40; G06Q 10/0639; G06Q 50/06; H02S 50/00

(52) U.S. Cl. CPC G01R 31/40; G06Q 10/06393; G06Q 50/06; H02S 50/00; H02S 20/23

(57) ABSTRACT

A building roof photovoltaic power quality evaluation method based on AHP and CRITIC-Entropy is provided. The method includes: obtaining data values of evaluation indicators of a building roof photovoltaic power quality, and constructing a judgment matrix and a probability matrix according to the data values of the evaluation indicators; processing the judgment matrix to obtain a subjective corresponding weight of each of the evaluation indicators by using an improved AHP method, and solving the probability matrix to obtain an objective corresponding weight of each of the evaluation indicators based on the CRITIC-Entropy; and integrating the subjective corresponding weights and the objective corresponding weights to obtain comprehensive weight coefficients, and determining a final evaluation result by the comprehensive weight coefficients and the probability matrix.

### FIELD OF THE INVENTION

The invention relates to the technical field of data analysis and statistics, in particular to a method for evaluating a building roof photovoltaic power quality based on AHP and CRITIC-Entropy.

### BACKGROUND OF THE INVENTION

Under the background of accelerating the construction of smart grid and the implementation of the double carbon policy of “carbon neutrality” and “carbon peak”, the photovoltaic industry has been developing rapidly. Based on the current situation that the population economy in the east and west of our country is contradictory with the photovoltaic resources, distributed photovoltaic has emerged. Distributed photovoltaic has made full use of the roof of urban and rural areas and even the idle area of the roof of the agricultural greenhouse, so as to realize the combination of energy utilization and benefit the people, and thus it is widely supported by the society and the government. However, due to the intermittency and volatility of photovoltaic power generation, the direct connection of distributed photovoltaic to the grid will cause various impacts on the distribution network and affect the power quality. Therefore, it is necessary to evaluate the power quality of distributed photovoltaic.

The current mainstream power quality evaluation methods are mainly, based on the experience of power experts, performing subjective weighting methods such as analytic hierarchy process (AHP) on related indicators that affect power quality. That is, even if a certain indicator fluctuates violently, according to the fixed weight allocation, the weight corresponding to that indicator cannot be increased accordingly, such that it cannot reflect the fluctuation of power quality well. Therefore, it is necessary to establish an evaluation method that can reflect the fluctuation characteristics of indicators to better deal with distributed photovoltaic equipment having large fluctuations.

### SUMMARY OF THE INVENTION

The purpose of this part is to outline some aspects of embodiments of the invention and to briefly introduce some better embodiments. Some simplifications or omissions may be made in this part and in the abstract of the specification and the title of the invention in this application to avoid ambiguity of the purpose of this part, the abstract of the specification and the title of the invention, and such simplifications or omissions shall not be used to limit the scope of the invention.

In view of the above existing problems, the present invention is proposed.

The technical problem solved by the invention is that the existing building roof photovoltaic power quality evaluation method is too narrow, and it relies too much on expert experience, and thus it is difficult to adapt to the problem of some power quality indicators having large fluctuation.

For solving the foregoing problems, in accordance to one aspect of the present invention, a method for evaluating building roof photovoltaic power quality based on Analytical Hierarchy Process (AHP) and CRITIC-Entropy is provided. The method comprises: obtaining data values of evaluation indicators of a building roof photovoltaic power quality, and constructing a judgment matrix and a probability matrix according to the data values of the evaluation indicators; processing the judgment matrix to obtain a subjective corresponding weight of each of the evaluation indicators by using an improved AHP method, and solving the probability matrix to obtain an objective corresponding weight of each of the evaluation indicators based on the CRITIC-Entropy; and integrating the subjective corresponding weights and the objective corresponding weights to obtain comprehensive weight coefficients, and determining a final evaluation result by the comprehensive weight coefficients and the probability matrix.

In an embodiment of the method, wherein the evaluation indicators of the building roof photovoltaic power quality comprise: harmonic amount, frequency offset and three-phase voltage imbalance.

In an embodiment of the method, wherein constructing the judgment matrix comprises: determining an importance level of each of the evaluation indicators, which are, from the largest to the smallest, the frequency deviation, the harmonic amount, the three-phase voltage imbalance, constructing the judgment matrix according to the importance levels of the evaluation indicators, wherein the judgment matrix comprising:

$$C = [ \begin{matrix}{c}_{11} & {c}_{12} & … & {c}_{1 m} \\ {c}_{21} & {c}_{21} & … & {c}_{2 m} \\ ⋮ & ⋮ & ⋮ & ⋮ \\ {c}_{m 1} & {c}_{m 2} & … & {c}_{m m}\end{matrix} ]$$

where cₘₘ represents each element of the judgment matrix obtained by comparing each pair of the evaluation indicators.

In an embodiment of the method, wherein constructing the probability matrix comprising: classifying, according to the specific rules in a national standard for each evaluation indicator of power quality, the evaluation indicators into five levels which are, from the smallest to the largest, excellent, good, medium, qualified and unqualified; analyzing collected data values of power according to classification results, so as to obtain the probability matrix; wherein calculation for the probability matrix F comprising:

$$F = \frac{1}{T} [ \begin{matrix}{t}_{f 1} & {t}_{f 2} & {t}_{f 3} & {t}_{f 4} & {t}_{f 5} \\ {t}_{x 1} & {t}_{x 2} & {t}_{x 3} & {t}_{x 4} & {t}_{x 5} \\ {t}_{h 1} & {t}_{h 2} & {t}_{h 3} & {t}_{h 4} & {t}_{h 5}\end{matrix} ]$$

where, T represents a presidential duration, t_{f1-5} represents a statistical duration of frequency deviation corresponding to one-five levels, tₓ₁₋₅ represents a statistical duration of harmonic amount corresponding to one-five levels, and tₕ₁₋₅ represents a statistical duration of three-phase unbalance corresponding to one-five levels.

In an embodiment of the method, wherein obtaining the subjective corresponding weigh comprising: obtaining a complete consistency matrix of the judgment matrix by the improved AHP method, and obtaining the subjective corresponding weight of each evaluation indicator of the building roof photovoltaic power quality by using a maximum feature root and feature vector of the complete consistency matrix; wherein the calculation of the subjective corresponding weight of each evaluation indicator of the building roof photovoltaic power quality comprising:

$$\overline{{w}_{ι}} = \sqrt[m]{{\prod }_{j = 1}^{m} {c}_{ij}^{*}} , i = 1 , 2 , 3 , … , m$$

where, w̅ₗ̅ represents m-power root of i^{th} row element product, cᵢⱼ* represents elements of the completely consistent matrix of the judgment matrix C, m represents total number of the evaluation indicators.

In an embodiment of the method, further comprising: performing m-power root processing to each row element product of the complete consistency matrix, and normalizing vectors obtained by the m-power root processing to obtain the subjective corresponding weight, wherein the calculation of the subjective corresponding weight comprising:

$$\overline{W} = {[ \overline{{w}_{1}} , \overline{{w}_{2}} , … , \overline{{w}_{m}} ]}^{T}$$

$${w}_{i} = \frac{\overline{{w}_{ι}}}{{\sum }_{j = 1}^{m} \overline{{w}_{j}}}$$

where W̅ represents vector obtained after the m-power root processing, w̅ₘ̅ represents a m-power root of a product of m^{th} evaluation indicator, w̅ⱼ̅ represents a m-power root of j^{th} column element product.

In an embodiment of the method, wherein obtaining the subjective corresponding weight comprising: determining entropy value and differentiation coefficient of each evaluation indicator by using an entropy weight method; obtaining the objective corresponding weight of each index according to the differentiation coefficient, wherein the calculation of the objective corresponding weight of each evaluation indicator comprising:

$${w}_{{e}_{i}} = \frac{{d}_{i}}{{\sum }_{i = 1}^{m} {d}_{i}}$$

where dᵢ represents a differentiation coefficient of evaluation indicator i.

In an embodiment of the method, further comprising: obtaining the objective corresponding weight of each evaluation indicator by using a CRITIC method according to a contrast value within each evaluation indicator and a conflict value between each evaluation indicator; the calculation for the objective corresponding weight W_{ci} comprising:

$${W}_{ci} = {C}_{i} / {\sum }_{i}^{m} {C}_{i}$$

where Cᵢ represents information amount included in i^{th} evaluation indicator; combining the objective corresponding weight calculated by the entropy weight method and the objective weight value calculated by the CRITIC method to obtain a combined objective corresponding weight of each evaluation indicator; the calculation of the combined objective corresponding weight Wₖᵢ comprising:

$${W}_{ki} = \frac{( {σ}_{i} + {e}_{i} ) {\sum }_{j = 1}^{n} ( 1 - {r}_{ij} )}{{\sum }_{i = 1}^{m} ( {σ}_{i} + {e}_{i} ) {\sum }_{j = 1}^{n} ( 1 - {r}_{ij} )}$$

where σᵢ represents a standard deviation of evaluation indicator i, eᵢ represents an entropy of evaluation indicator i, and rᵢⱼ represents a correlation coefficient between evaluation indicators i and j.

In an embodiment of the method, wherein obtaining the comprehensive weight coefficients comprising:

w_{zi}=awᵢ+bwₖᵢ

where, w_{zi} represents the comprehensive weight coefficient of i^{th} evaluation indicator, a represents a comprehensive assignment coefficient for the subjective corresponding weight, and b represents a comprehensive assignment coefficient for the combined objective corresponding weight.

In an embodiment of the method, wherein determining the final evaluation result comprising:

B=w_{zi}·F

where B represents evaluation results; performing weighted average on the evaluation results to obtain the final evaluation result, and the calculation of the final evaluation result B̅ comprises:

$$\overline{B} = \frac{{\sum }_{x = 1}^{n} {xb}_{x}}{{\sum }_{x = 1}^{n} {b}_{x}}$$

where x represents total number of each evaluation indicator, and bₓ represents the evaluation result of x^{th} evaluation indicator.

Based on above, the building roof photovoltaic power quality evaluation method based on AHP and CRITIC-Entropy provided by foregoing embodiments is capable of, finding subjective weight on each evaluation indicator according to influencing factors of power quality by using the improved AHP to combine with expert experience, using a hybrid algorithm of CRITIC-Entropy to analyze each indicator affecting the power quality, and finding objective wight according to internal relationship between each indicators, contrast and conflict of each indicator, such that the scientific and practical of power quality evaluation is effectively improved, and provided power quality evaluation services for building roof photovoltaic system is more accurate.

### BRIEF DESCRIPTION OF THE DRAWINGS

Embodiments of the invention are described in more details hereinafter with reference to the drawings, in which:

FIG. 1 shows the overall flow chart of a building roof photovoltaic power quality evaluation method based on AHP and CRITIC-Entropy provided by an embodiment of the invention;

FIG. 2 shows the sampling diagram of the grid frequency in the building roof photovoltaic power quality evaluation method based on AHP and CRITIC-Entropy provided by second embodiment of the invention;

FIG. 3 shows the sampling diagram of the total voltage harmonic rate in the building roof photovoltaic power quality evaluation method based on AHP and CRITIC-Entropy provided by the second embodiment of the invention; and

FIG. 4 shows the sampling diagram of the three-phase voltage imbalance degree in the building roof photovoltaic power quality evaluation method based on AHP and CRITIC-Entropy provided by the second embodiment of the invention.

### DETAILED DESCRIPTION

In order to make the above purposes, features and advantages of the invention more obvious and easy to understand, the specific embodiments of the invention are explained in detail in the following with the drawings attached to the specification. Obviously, the embodiments described are part of the embodiments of the invention, but not all of the embodiments. Based on the embodiments of the present invention, all other embodiments obtained by ordinary persons in the field without creative labor shall fall within the scope of the protection of the present invention.

Many specific details are described in the following description in order to fully understand the invention, but the invention can also be implemented in other ways different from those described herein, and persons skilled in the art can do similar promotion without violating the meaning of the invention, so the invention is not limited by the specific embodiment disclosed below.

Secondly, the “one embodiment” or “embodiment” herein refers to a specific feature, structure or feature that can be included in at least one implementation of the invention. The words “in one embodiment” appearing in different places in this specification do not all refer to the same embodiment, nor are they separate or selectively mutually exclusive with other embodiments.

The invention is described in detail in combination with the schematic diagram. When detailing the embodiments of the invention, for the convenience of explanation, the sectional view representing the device structure will not be locally enlarged in general scale, and the schematic diagram is only an example, which should not limit the scope of protection of the invention. In addition, the actual production shall include the three-dimensional space dimensions of length, width and depth.

At the same time, in the description of the invention, it should be noted that the orientation or position relationship indicated by “up, down, inside and outside” in the terminology is based on the orientation or position relationship shown in the drawings, which is only for the convenience of describing the invention and simplifying the description, rather than indicating or implying that the device or element referred to must have a specific orientation, be constructed and operated in a specific orientation, so it cannot be understood as a limitation of the invention. In addition, the term “first, second or third” is used only for descriptive purposes and cannot be understood as indicating or implying relative importance.

Unless otherwise specified and defined in the invention, the term “installation, connection, connection” should be understood in a broad sense, for example, it can be fixed connection, removable connection or integrated connection; It can also be mechanical connection, electrical connection or direct connection, or indirect connection through intermediate media, or internal connection of two components. For ordinary technicians in the art, the specific meaning of the above terms in the invention can be understood in specific cases.

### EMBODIMENT 1

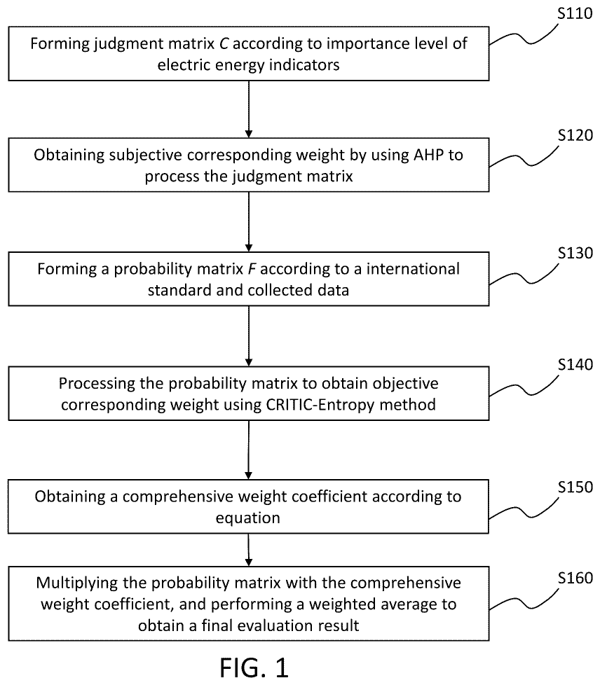

Referring to FIG. 1 for an embodiment of the invention, an AHP and critical-entropy based building roof photovoltaic power quality evaluation method is provided, including steps S1 to S3.

S1: obtaining data values of evaluation indicators of a building roof photovoltaic power quality, and constructing a judgment matrix and a probability matrix according to the data values of the evaluation indicators.

Specifically, the evaluation indicators of the building roof photovoltaic power quality comprise: harmonic amount, frequency offset and three-phase voltage imbalance.

Further, the importance level of each evaluation index is determined according to the expert opinions, which are, from the largest to the smallest, the frequency deviation, the harmonic amount, the three-phase voltage imbalance.

The judgment matrix is constructed according to the importance levels of the evaluation indicators, wherein the calculation of the judgment matrix includes:

$$C = [ \begin{matrix}{c}_{11} & {c}_{12} & … & {c}_{1 m} \\ {c}_{21} & {c}_{21} & … & {c}_{2 m} \\ ⋮ & ⋮ & ⋮ & ⋮ \\ {c}_{m 1} & {c}_{m 2} & … & {c}_{mm}\end{matrix} ]$$

where cₘₘ represents each element of the judgment matrix obtained by comparing each pair of the evaluation indicators.

It should be mentioned that the determination of value of the element at row i and column j of the judgment matrix includes: if element j is more important than element i, the value of the judgment matrix is determined as −1; if element j and element i are equally important, the value of the judgment matrix is determined as 0; if element i is more important than element j, the value of the judgment matrix is determined as 1.

In the present invention, the judgment matrix constructed according to the expert opinions is presented as below,

$$C = [ \begin{matrix}0 & 1 & 1 \\ - 1 & 0 & 1 \\ - 1 & - 1 & 0\end{matrix} ]$$

It should be noted that the rows and columns of the judgment matrix represent frequency deviation, harmonic amount and three-phase voltage imbalance, respectively.

Further, according to the specific provisions of each indicator of power quality in the national standard, each indicator is classified into five levels, from smallest to largest, they are respectively excellent, good, medium, qualified and unqualified.

The specific classification is shown in Table 1 below.

TABLE 1
the classification of evaluation indicators

| | | | Three-phase |
|---|---|---|---|
| | Frequency | Harmonic | voltage |
| Level | deviation/Hz | amount/% | imbalance/% |
| 1 | ≤0.05 | ≤1 | ≤0.5 |
| 2 | ≤0.1 | ≤2 | ≤1 |
| 3 | ≤0.15 | ≤3 | ≤1.5 |
| 4 | ≤0.2 | ≤4 | ≤2 |
| 5 | >0.2 | >4 | >2 |

Collected data values of power is analyzed according to classification results, so as to obtain the probability matrix, wherein the calculation for the probability matrix F includes:

$$F = \frac{1}{T} [ \begin{matrix}{t}_{f 1} & {t}_{f 2} & {t}_{f 3} & {t}_{f 4} & {t}_{f 5} \\ {t}_{x 1} & {t}_{x 2} & {t}_{x 3} & {t}_{x 4} & {t}_{x 5} \\ {t}_{h 1} & {t}_{h 2} & {t}_{h 3} & {t}_{h 4} & {t}_{h 5}\end{matrix} ]$$

where, T represents a presidential duration, t_{f1-5} represents a statistical duration of frequency deviation corresponding to one-five levels, tₓ₁₋₅ represents a statistical duration of harmonic amount corresponding to one-five levels, and tₕ₁₋₅ represents a statistical duration of three-phase unbalance corresponding to one-five levels.

S2: processing the judgment matrix to obtain a subjective corresponding weight of each of the evaluation indicators by using an improved AHP method, and solving the probability matrix to obtain an objective corresponding weight of each of the evaluation indicators based on the CRITIC-Entropy.

Specifically, a complete consistency matrix of the judgment matrix is obtained by the improved AHP method, and the subjective corresponding weight of each evaluation indicator of the building roof photovoltaic power quality is obtained by using a maximum feature root and feature vector of the complete consistency matrix.

The calculation of the subjective corresponding weight of each evaluation indicator of the building roof photovoltaic power quality includes:

$$\overline{{w}_{ι}} = \sqrt[m]{{\prod }_{j = 1}^{m} {c}_{ij}^{*}} , i = 1 , 2 , 3 , … , m$$

where, w̅ₗ̅ represents m-power root of i^{th} row element product, cᵢⱼ* represents elements of the completely consistent matrix of the judgment matrix C, m represents total number of the evaluation indicators. The total number of the evaluation indicators is set, for example, as 3 in the embodiment.

Furthermore, performing m-power root processing to each row element product of the complete consistency matrix, and normalizing vectors obtained by the m-power root processing to obtain the subjective corresponding weight, wherein the calculation of the subjective corresponding weight includes,

$$\overline{W} = {[ \overline{{w}_{1}} , \overline{{w}_{2}} , … , \overline{{w}_{m}} ]}^{T}$$

$${w}_{i} = \frac{\overline{{w}_{ι}}}{{\sum }_{j = 1}^{m} \overline{{w}_{j}}}$$

where W̅ represents vector obtained after the m-power root processing, w̅ₘ̅ represents a m-power root of a product of m^{th} evaluation indicator, w̅ⱼ̅ represents a m-power root of j^{th} column element product.

It should be mentioned that using the improved analytic hierarchy process to obtain the complete consistency matrix of the judgment matrix including:
(1) The relevant definitions of antisymmetric matrix is as follows,
Definition 1: if element in a real matrix A satisfies αᵢⱼ=−αⱼᵢ, where ∀i , j∈N, the real matrix A is determined as the antisymmetric matrix.
Definition 2: when the antisymmetric matrix A satisfies αᵢⱼ=αᵢₖ+αₖⱼ, the antisymmetric matrix A is determined as a transfer matrix.
Definition 3: if B is the most optimal transfer matrix of A, Σᵢ₌₁^{m}Σⱼ₌₁^{m}(bᵢⱼ−αᵢⱼ)² will get a minimum value.
(2) The related theorem of the optimal transfer matrix are as follows,

Theorem 1: If matrix element satisfies

$${b}_{ij} = \frac{1}{m} {\sum }_{k = 1}^{m} ( {c}_{ik} - {c}_{jk} ) ,$$

the matrix B is determined as an optimal transfer matrix of matrix C. Accordingly, judgment matrix C is the antisymmetric matrix, and thus each element of the optimal transfer matrix B of the judgment matrix C satisfies

$${b}_{i j} = \frac{1}{n} {\sum }_{k = 1}^{m} ( {c}_{i k} - {c}_{j k} ) = \frac{1}{n} {\sum }_{k = 1}^{m} ( {c}_{i k} + {c}_{k j} ) .$$

(3) The relevant definition and theorem of constructing complete consistency matrix are:
Definition 4: if the elements of matrix A satisfy αᵢₖαₖⱼ=αᵢⱼ, A is determined as a completely consistent matrix.

Theorem 2: for the antisymmetric matrix A, matrix B is the optimal transfer matrix for matrix A, then A*=e^{B} is the complete consistency matrix of A;

Moreover, obtaining the objective corresponding weight including:

Determining entropy value and differentiation coefficient of each evaluation indicator by using an entropy weight method, wherein the calculation of the entropy value of each indicator includes:

$${e}_{i} = - \frac{1}{ln n} {\sum }_{j = 1}^{n} {f}_{i j} \cdot ln {f}_{i j}$$

Where, eᵢ represents the entropy value of the i^{th} indicator, n represents the number of indicator grades, and fᵢⱼ represents the element of the i^{th} row and j^{th} column in the probability matrix. When fᵢⱼ=0 or fᵢⱼ=1, determining that fᵢⱼ·ln fᵢⱼ=0.

The calculation of the differentiation coefficient includes:

dᵢ=1−eᵢ

Where dᵢ represents the differentiation coefficient of indicator i.

The objective corresponding weight of each indicator is obtained according to the differentiation coefficient, wherein the calculation of the objective corresponding weight wₑ_{ᵢ} of each evaluation indicator including:

$${w}_{{e}_{i}} = \frac{{d}_{i}}{{\sum }_{i = 1}^{m} {d}_{i}}$$

obtaining the objective corresponding weight of each evaluation indicator by using a CRITIC method according to a contrast value within each evaluation indicator and a conflict value between each evaluation indicator, and the calculation for the objective corresponding weight W_{ci} includes:

$${W}_{c i} = {C}_{i} / {\sum }_{i}^{m} {C}_{i}$$

where Cᵢ represents information amount included in i^{th} evaluation indicator.

It should be mentioned that the calculation of the information amount included in i^{th} evaluation indicator includes:

$${C}_{i} = {δ}_{i} {\sum }_{j = 1}^{n} ( 1 - {r}_{i j} )$$

Where, δᵢ represents the standard deviation, and rᵢⱼ represents the correlation coefficient between evaluation indicator i and index j. The greater Cᵢ is, the more information amount included in the i^{th} indicator, and the greater importance level of that indicator correspondingly.

Furthermore, combining the objective corresponding weight calculated by the entropy weight method and the objective weight value calculated by the CRITIC method to obtain a combined objective corresponding weight of each evaluation indicator, wherein the calculation of the combined objective corresponding weight Wₖᵢ includes:

$${W}_{k i} = \frac{( {σ}_{i} + {e}_{i} ) {\sum }_{j = 1}^{n} ( 1 - {r}_{i j} )}{{\sum }_{i = 1}^{m} ( {σ}_{i} + {e}_{i} ) {\sum }_{j = 1}^{n} ( 1 - {r}_{i j} )}$$

where σᵢ represents a standard deviation of evaluation indicator i, eᵢ represents an entropy of evaluation indicator i, and rᵢⱼ represents a correlation coefficient between evaluation indicators i and j.

S3: integrating the subjective corresponding weights and the objective corresponding weights to obtain comprehensive weight coefficients, and determining a final evaluation result by the comprehensive weight coefficients and the probability matrix.

Specifically, obtaining the comprehensive weight coefficients including:

w_{zi}=awᵢ+bwₖᵢ

where, w_{zi} represents the comprehensive weight coefficient of i^{th} evaluation indicator, a represents a comprehensive assignment coefficient for the subjective corresponding weight, and b represents a comprehensive assignment coefficient for the combined objective corresponding weight, satisfying a+b=1, wherein a=b=0.5 in the embodiment.

Moreover, determining the final evaluation result including:

B=w_{zi}·F

where B represents evaluation results.

In more detail, weighted average is performed on the evaluation results to obtain the final evaluation result, and the calculation of the final evaluation result B̅ comprises:

$$\overline{B} = \frac{{\sum }_{x = 1}^{n} x {b}_{x}}{{\sum }_{x = 1}^{n} {b}_{x}}$$

where x represents total number of each evaluation indicator, and bₓ represents the evaluation result of x^{th} evaluation indicator.

It should be noted that the embodiment provides a photovoltaic power quality evaluation method for building roof based on AHP and CRITIC-Entropy, which, for the influencing factors of power quality, the improved analytic hierarchy process combined with expert experience is used to carry out subjective weight for each evaluation indicator. In addition, the hybrid CRITIC-Entropy algorithm is used to analyze each indicator affecting the power quality; and the objective weight of each indicator is solved comprehensively according to the internal relationship of each indicator and the contrast and conflict of the indicators, which can more effectively improve the scientific and practical of power quality evaluation, and provide more accurate power quality evaluation services for the building roof photovoltaic system.

### EMBODIMENT 2

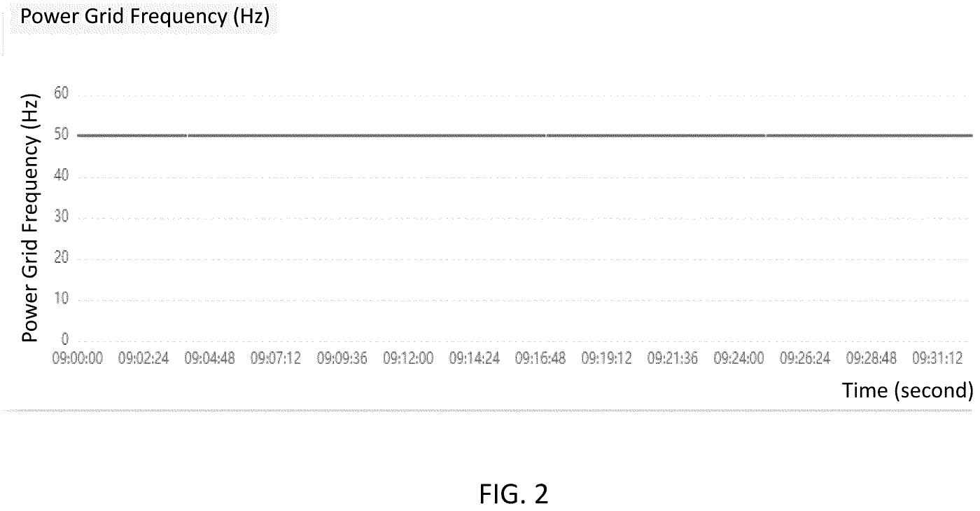

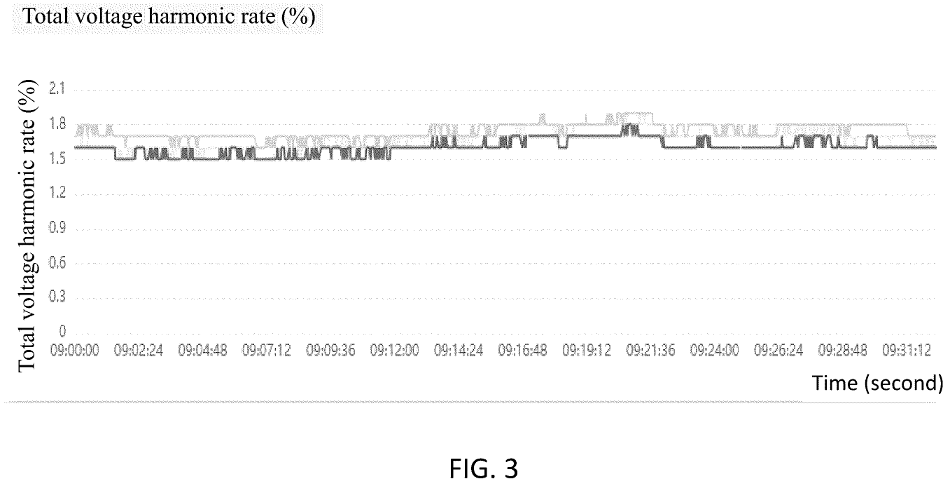

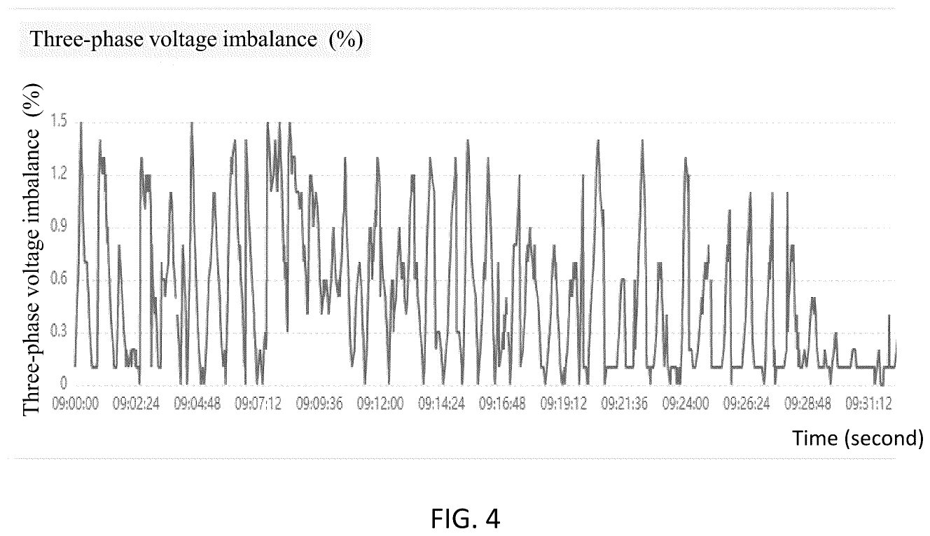

Referring to FIGS. 2 to 4 for the embodiment 2 of the invention. This embodiment is different from the embodiment 1 in that it provides the verification test of the building roof photovoltaic power quality evaluation method based on AHP and CRITIC-Entropy. To verify the technical effect of this method, this embodiment uses the traditional technical scheme to compare with the method of the invention, and compares the test results by means of scientific demonstration, so as to verify the real effect of the provided method.

Selecting the short-term power prediction of building roof photovoltaic in Jiangning District of Nanjing City, which includes 1 h data of two users' roofs, taking 1 second as an sampling interval, and thus 3600 data points per hour. According to the actual data set, the input sequence is 3600*3 photovoltaic power quality indicator data with a sampling frequency of 1 s from 9:00-10:00 for one hour in a row. FIGS. 2 to 4 are the sampling charts of the three indicators of the invention from 9:00-9:30.

Table 1 shows the statistics of the time when each electrical energy indicators of the roofs of two users are at each level, and Table 2 shows the comparison of the evaluation results based on AHP and CRITIC-Entropy methods provided by the conventional method and the invention.

TABLE 1
Time statistics of evaluation indicators at each level

| | Energy | Time Statistics | | | | |
|---|---|---|---|---|---|---|
| User | Indicators | Level1 | Level2 | Level3 | Level4 | Level5 |
| User1 | Frequency | 3600 | 0 | 0 | 0 | 0 |
| | deviation | | | | | |
| | Harmonic amount | 0 | 2657 | 943 | 0 | 0 |
| | Three-phase | 2431 | 790 | 375 | 4 | 0 |
| | voltage imbalance | | | | | |
| User2 | Frequency | 3600 | 0 | 0 | 0 | 0 |
| | deviation | | | | | |
| | Harmonic amount | 963 | 1032 | 1605 | 0 | 0 |
| | Three-phase | 0 | 0 | 0 | 342 | 3258 |
| | voltage imbalance | | | | | |

TABLE 2
Power Quality Evaluation Results of User 1 and User 2

| | | Evaluation |
|---|---|---|
| User | Evaluation Method | results |
| User1 | Conventional AHP | 1.832 |
| | AHP and CRITIC-Entropy | 1.798 |
| | (The provided method) | |
| User2 | Conventional AHP | 1.973 |
| | AHP and CRITIC-Entropy | 2.579 |
| | (The provided method) | |

From Table 1, it can be seen that the fluctuation of each electric energy indicator of User 1 is small, and variation of the Three-phase imbalance indicator of User 2 is much more than those of the Frequency deviation and Harmonic amount indicators. It can be seen from Table 2 that the two methods have relatively similar results when evaluating User 1, while the difference becomes large when evaluating User 2. When evaluating User 2, the corresponding weight should be increased in view of the dramatic change of three-phase imbalance, but the traditional method does not change the corresponding weight, which does not fit the objective reality. However, the method of the invention can effectively reflect the change of indicators, and correspondingly increase the proportion of its weight, Therefore, the invention can more effectively reflect the objective reality and indicator fluctuation.

It should be noted that the above embodiments are only used to illustrate the technical solution of the invention rather than limit it. Although the invention has been described in detail with reference to better embodiments, ordinary technicians in the art should understand that the technical solution of the invention can be modified or replaced equivalently without departing from the spirit and scope of the technical solution of the invention, which should be covered in the scope of claims of the invention.

What is claimed is:

1. A method for evaluating building roof photovoltaic power quality based on Analytical Hierarchy Process (AHP) and CRITIC-Entropy, comprising:
obtaining data values of evaluation indicators of a building roof photovoltaic power quality, and constructing a judgment matrix and a probability matrix according to the data values of the evaluation indicators;
processing the judgment matrix to obtain a subjective corresponding weight of each of the evaluation indicators by using an improved AHP method, and solving the probability matrix to obtain an objective corresponding weight of each of the evaluation indicators based on the CRITIC-Entropy; and
integrating the subjective corresponding weights and the objective corresponding weights to obtain comprehensive weight coefficients, and determining a final evaluation result by the comprehensive weight coefficients and the probability matrix.

2. The method for evaluating the building roof photovoltaic power quality based on the AHP and the CRITIC-Entropy of claim 1, wherein the evaluation indicators of the building roof photovoltaic power quality comprise: harmonic amount, frequency offset and three-phase voltage imbalance.

3. The method for evaluating the building roof photovoltaic power quality based on the AHP and the CRITIC-Entropy of claim 2, wherein constructing the judgment matrix comprises:
determining an importance level of each of the evaluation indicators, which are, from the largest to the smallest, the frequency deviation, the harmonic amount, the three-phase voltage imbalance,
constructing the judgment matrix according to the importance levels of the evaluation indicators, wherein the judgment matrix comprising:
$$C = [ \begin{matrix}{c}_{11} & {c}_{12} & … & {c}_{1 m} \\ {c}_{21} & {c}_{21} & … & {c}_{2 m} \\ ⋮ & ⋮ & ⋮ & ⋮ \\ {c}_{m 1} & {c}_{m 2} & … & {c}_{mm}\end{matrix} ]$$
where cₘₘ represents each element of the judgment matrix obtained by comparing each pair of the evaluation indicators.

4. The method for evaluating the building roof photovoltaic power quality based on the AHP and the CRITIC-Entropy of claim 3, wherein constructing the probability matrix comprising:
classifying, according to the specific rules in a national standard for each evaluation indicator of power quality, the evaluation indicators into five levels which are, from the smallest to the largest, excellent, good, medium, qualified and unqualified;
analyzing collected data values of power according to classification results, so as to obtain the probability matrix;
wherein calculation for the probability matrix F comprising:
$$F = \frac{1}{T} [ \begin{matrix}{t}_{f 1} & {t}_{f 2} & {t}_{f 3} & {t}_{f 4} & {t}_{f 5} \\ {t}_{x 1} & {t}_{x 2} & {t}_{x 3} & {t}_{x 4} & {t}_{x 5} \\ {t}_{h 1} & {t}_{h 2} & {t}_{h 3} & {t}_{h 4} & {t}_{h 5}\end{matrix} ]$$
where, T represents a presidential duration, t_{f1-5} represents a statistical duration of frequency deviation corresponding to one-five levels, tₓ₁₋₅ represents a statistical duration of harmonic amount corresponding to one-five levels, and tₕ₁₋₅ represents a statistical duration of three-phase unbalance corresponding to one-five levels.

5. The method for evaluating the building roof photovoltaic power quality based on the AHP and the CRITIC-Entropy of claim 4, wherein obtaining the subjective corresponding weigh comprising:
obtaining a complete consistency matrix of the judgment matrix by the improved AHP method, and obtaining the subjective corresponding weight of each evaluation indicator of the building roof photovoltaic power quality by using a maximum feature root and feature vector of the complete consistency matrix;
wherein the calculation of the subjective corresponding weight of each evaluation indicator of the building roof photovoltaic power quality comprising:
$$\overline{{w}_{ι}} = \sqrt[m]{{\prod }_{j = 1}^{m} {c}_{i j}^{*}} , i = 1 , 2 , 3 , … , m$$
where, w̅ₗ̅ represents m-power root of i^{th} row element product, cᵢⱼ* represents elements of the completely consistent matrix of the judgment matrix C, m represents total number of the evaluation indicators.

6. The method for evaluating the building roof photovoltaic power quality based on the AHP and the CRITIC-Entropy of claim 5, further comprising:
performing m-power root processing to each row element product of the complete consistency matrix, and normalizing vectors obtained by the m-power root processing to obtain the subjective corresponding weight,
wherein the calculation of the subjective corresponding weight comprising:
$$\overline{W} = {[ \overline{{w}_{1} ,} \overline{{w}_{2} ,} … , \overline{{w}_{m}} ]}^{T}$$
$${w}_{i} = \frac{\overline{{w}_{ι}}}{{\sum }_{j = 1}^{m} \overline{{w}_{j}}}$$
where W̅ represents vector obtained after the m-power root processing, w̅ₘ̅ represents a m-power root of a product of m^{th} evaluation indicator, w̅ⱼ̅ represents a m-power root of j^{th} column element product.

7. The method for evaluating the building roof photovoltaic power quality based on the AHP and the CRITIC-Entropy of claim 6, wherein obtaining the objective corresponding weight comprising:
determining entropy value and differentiation coefficient of each evaluation indicator by using an entropy weight method;
obtaining the objective corresponding weight of each evaluation indicator according to the differentiation coefficient,
wherein the calculation of the objective corresponding weight of each evaluation indicator comprising:
$${w}_{{e}_{i}} = \frac{{d}_{i}}{{\sum }_{i = 1}^{m} {d}_{i}}$$
where dᵢ represents a differentiation coefficient of evaluation indicator i.

8. The method for evaluating the building roof photovoltaic power quality based on the AHP and the CRITIC-Entropy of claim 7, further comprising:
obtaining the objective corresponding weight of each evaluation indicator by using a CRITIC method according to a contrast value within each evaluation indicator and a conflict value between each evaluation indicator;
the calculation for the objective corresponding weight W_{ci} comprising:
$${W}_{c i} = {C}_{i} / {\sum }_{i}^{m} {C}_{i}$$
where Cᵢ represents information amount included in i^{th} evaluation indicator;
combining the objective corresponding weight calculated by the entropy weight method and the objective weight value calculated by the CRITIC method to obtain a combined objective corresponding weight of each evaluation indicator;
the calculation of the combined objective corresponding weight Wₖᵢ comprising:
$${W}_{k i} = \frac{( {σ}_{i} + {e}_{i} ) {\sum }_{j = 1}^{n} ( 1 - {r}_{i j} )}{{\sum }_{i = 1}^{m} ( {σ}_{i} + {e}_{i} ) {\sum }_{j = 1}^{n} ( 1 - {r}_{i j} )}$$
where σᵢ represents a standard deviation of evaluation indicator i, eᵢ represents an entropy of evaluation indicator i, and rᵢⱼ represents a correlation coefficient between evaluation indicators i and j.

9. The method for evaluating the building roof photovoltaic power quality based on the AHP and the CRITIC-Entropy of claim 8, wherein obtaining the comprehensive weight coefficients comprising:
w_{zi}=awᵢ+bwₖᵢ
where, w_{zi} represents the comprehensive weight coefficient of i^{th} evaluation indicator, a represents a comprehensive assignment coefficient for the subjective corresponding weight, and b represents a comprehensive assignment coefficient for the combined objective corresponding weight.

10. The method for evaluating the building roof photovoltaic power quality based on the AHP and the CRITIC-Entropy of claim 9, wherein determining the final evaluation result comprising:
B=w_{zi}·F
where B represents evaluation results;
performing weighted average on the evaluation results to obtain the final evaluation result, and the calculation of the final evaluation result B̅ comprises:
$$\overline{B} = \frac{{\sum }_{x = 1}^{n} x {b}_{x}}{{\sum }_{x = 1}^{n} {b}_{x}}$$
where x represents total number of each evaluation indicator, and bₓ represents the evaluation result of x^{th} evaluation indicator.
